(19) United States
(12) Patent Application Publication
(10) Pub. No.: US 2026/0205062 A1
(43) Pub. Date: Jul. 16, 2026

(54) Polar Amplifier with Dynamic Cascode Biasing

(71) Applicant: Apple Inc., Cupertino, CA (US)

(72) Inventors: Haowei Jiang, San Diego, CA (US); Siwei Li, San Diego, CA (US); Ming-Da Tsai, San Jose, CA (US); Kefei Wu, San Diego, CA (US)

(21) Appl. No.: 19/016,634

(22) Filed: Jan. 10, 2025

(51) Int. Cl. H03F 1/32; H03F 3/24

(52) U.S. Cl. CPC H03F 1/32; H03F 3/245; H03F 2200/451

(57) ABSTRACT

An electronic device may include wireless circuitry with a polar amplifier that outputs a radio-frequency signal. The amplifier may include a first and second common source stages and first and second cascode stages coupled between a power supply voltage and a reference voltage. The power supply voltage may carry an amplitude modulation for the radio-frequency signal. Gate terminals of the common source stages may receive local oscillator signals that carry a phase modulation for the radio-frequency signal. A dynamic charge pump may be coupled between the power supply input and gate terminals of the first cascode stage. Dynamic level shifters may be coupled to the charge pump. The level shifters and the charge pump may produce a voltage at the gate terminals of the first cascode stage that tracks the power supply voltage without clipping, even as the power supply voltage drops to magnitudes close to zero.

### FIELD

This disclosure relates generally to electronic devices, including electronic devices with wireless circuitry.

### BACKGROUND

Electronic devices can be provided with wireless communications capabilities. An electronic device with wireless communications capabilities has wireless circuitry with one or more antennas. Wireless transceiver circuitry in the wireless circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. It can be difficult to provide power amplifiers with sufficient levels of performance. For example, if care is not taken, a power amplifier may exhibit insufficient dynamic range and linearity, which can limit the radio-frequency performance of the wireless circuitry.

### SUMMARY

An electronic device may include wireless circuitry. The wireless circuitry may include a transmit path. The transmit path may include a polar power amplifier that outputs a radio- frequency signal. The amplifier may include a first common source stage, a first cascode stage, a second cascode stage, and a second common source stage coupled in series between a power supply input and a reference voltage. The power supply input may receive a power supply voltage that carries an amplitude modulation for the radio-frequency signal. Gate terminals of transistors in the first and second common source stage may receive local oscillator signals that carry a phase modulation for the radio-frequency signal. Gate terminals of the first cascode stage (e.g., a PMOS cascode stage) may be coupled to a cascode node.

A dynamic charge pump may be coupled between the power supply input and the cascode node. The dynamic charge pump may include a capacitor coupled between the power supply input and the cascode node. The dynamic charge pump may also include cross-coupled inverters with power supply terminals coupled between the power supply input and the cascode node. First and second dynamic level shifters may be coupled to the dynamic charge pump. Each dynamic level shifter may include an inverter that is powered by a bias voltage and that receives the local oscillator signals. The dynamic level shifters and the dynamic charge pump may produce a voltage at the cascode node that tracks the power supply voltage without clipping, even as the power supply voltage drops to magnitudes close to zero.

An aspect of the disclosure provides amplifier circuitry configured to output a radio- frequency signal. The amplifier circuitry can include a first common source stage configured to receive a power supply voltage that conveys an amplitude modulation for the radio-frequency signal. The amplifier circuitry can include a first cascode stage that includes a first transistor and a second transistor having gate terminals coupled to a cascode node. The amplifier circuitry can include a second cascode stage, wherein the first cascode stage is coupled between the second cascode stage and the first common source stage. The amplifier circuitry can include a second common source stage coupled to a reference voltage, wherein the second cascode stage is coupled between the second common source stage and the first cascode stage. The amplifier circuitry can include cross-coupled inverters having power supply inputs coupled between the power supply voltage and the cascode node.

An aspect of the disclosure provides amplifier circuitry configured to output a radio- frequency signal. The amplifier circuitry can include a first common source stage that includes a first transistor and a second transistor, wherein a gate terminal of the first transistor receives a positive local oscillator signal and a gate terminal of the second transistor receives a negative local oscillator signal. The amplifier circuitry can include a cascode stage, wherein the cascode stage comprises a third transistor and a fourth transistor, the first transistor is coupled in series between the third transistor and a power supply input of the amplifier circuitry, the second transistor is coupled in series between the fourth transistor and the power supply input, and gate terminals of the third and fourth transistors are coupled to a cascode node. The amplifier circuitry can include a first circuit configured to generate at least part of a voltage at the cascode node based on the positive local oscillator signal. The amplifier circuitry can include a second circuit configured to generate at least part of the voltage at the cascode node based on the negative local oscillator signal.

An aspect of the disclosure provides a polar power amplifier. The polar power amplifier can include a first transistor having a gate terminal that receives a positive clocking signal. The polar power amplifier can include a second transistor having a gate terminal that receives a negative clocking signal, the first and second transistors having source terminals coupled to a power supply input. The polar power amplifier can include a third transistor having a source terminal coupled to a drain terminal of the first transistor. The polar power amplifier can include a fourth transistor having a source terminal coupled to a drain terminal of the second transistor, the third and fourth transistors having gate terminals coupled to a circuit node. The polar power amplifier can include a first capacitor coupled in series between the power supply input and the circuit node. The polar power amplifier can include a first inverter having power supply terminals coupled between the power supply input and the circuit node. The polar power amplifier can include a second inverter having power supply terminals coupled between the power supply input and the circuit node. The polar power amplifier can include a third inverter having an input that receives the positive clocking signal and having an output communicatively coupled to an input of the first inverter and an output of the second inverter. The polar power amplifier can include a fourth inverter having an input that receives the negative clocking signal and having an output communicatively coupled to an input of the second inverter and an output of the first inverter.

### BRIEF DESCRIPTION OF THE DRAWINGS

FIG. 1 is a diagram of an illustrative electronic device that includes wireless circuitry in accordance with some embodiments.

FIG. 2 is a diagram of illustrative wireless circuitry that includes radio-frequency amplifiers in accordance with some embodiments. FIG. 3 is a diagram of illustrative transmit circuitry that includes a polar amplifier in accordance with some embodiments.

FIG. 4 is a circuit diagram of an illustrative polar amplifier with dynamic cascode biasing in accordance with some embodiments. FIG. 5 is a plot illustrating power supply voltage and cascode voltage over time in a polar amplifier of the type shown in FIG. 4 in accordance with some embodiments. FIG. 6 is a plot of voltage waveforms at different nodes of a polar amplifier of the type shown in FIG. 4 in accordance with some embodiments. FIG. 7 is a plot illustrating how dynamic cascode biasing in a polar amplifier of the type shown in FIG. 4 may reduce amplitude modulation to amplitude modulation (AMAM) distortion and amplitude modulation to phase modulation (AMPM) distortion of the polar amplifier in accordance with some embodiments.

FIG. 8 is a plot illustrating how dynamic cascode biasing in a polar amplifier of the type shown in FIG. 4 may reduce adjacent channel leakage ratio (ACLR) of the polar amplifier in accordance with some embodiments.

### DETAILED DESCRIPTION

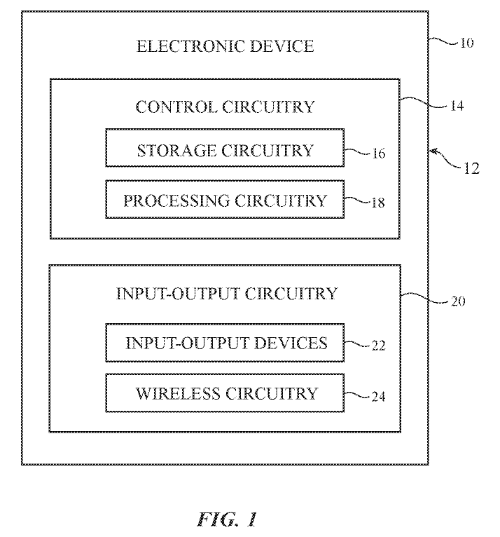

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access- memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols - sometimes referred to as Wi-Fi®), protocols for other short-range wireless communications links such as the Bluetooth® protocol or other wireless personal area network (WPAN) protocols, IEEE 802.11 ad protocols (e.g., ultra- wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), satellite communications (satcom) protocols, antenna-based spatial ranging protocols, optical communications protocols, or any other desired communications protocols. Each communications protocol may be associated with a corresponding radio access technology (RAT) that specifies the physical connection methodology used in implementing the protocol. Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio- frequency signal transmission and/or reception for device 10. Wireless circuitry 24 may be used for wireless communications. Wireless communications performed by wireless circuitry 24 may include or involve wireless data communications (e.g., where wireless data is carried by radio- frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a "band"). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10- 100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra- wideband (UWB) frequency bands that operate under the IEEE 802.15.4 protocol and/or other ultra-wideband communications protocols, satellite communications (satcom) bands (e.g., an IEEE C band (4-8 GHz), S band (2-4 GHz), L band (1-2 GHz), X band (8-12 GHz), W band (75- 110 GHz), V band (40-75 GHz), K band (18-27 GHz), Kₐ band (26.5-40 GHz), Ku band (12-18 GHz), etc.), unlicensed bands, communications bands under the family of 3GPP wireless communications standards, communications bands under the IEEE 802.XX family of standards, and/or any other desired frequency bands of interest.

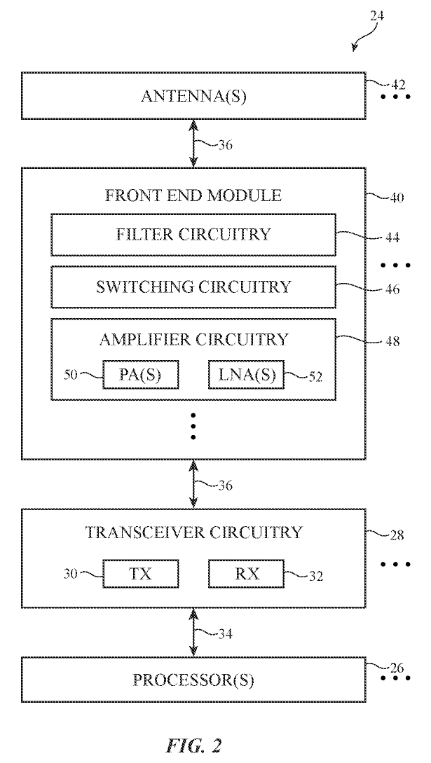

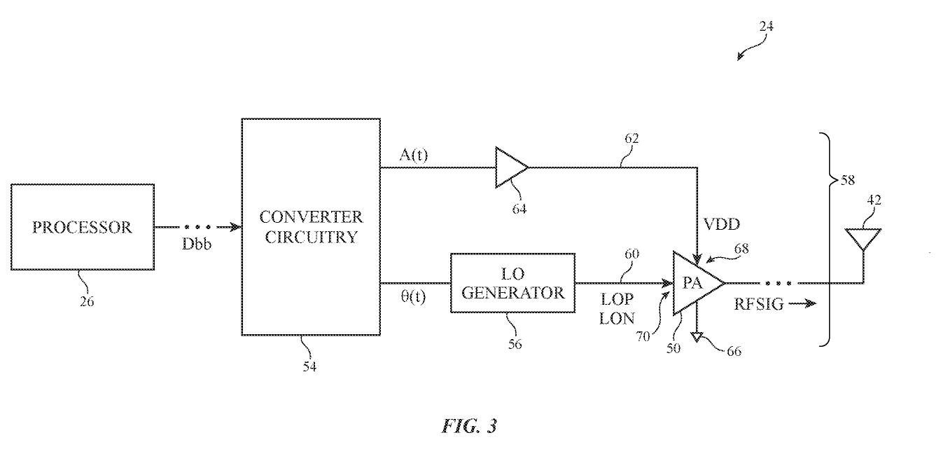

FIG. 2 is a diagram showing illustrative components within wireless circuitry 24. As shown in FIG. 2, wireless circuitry 24 may include a processor such as processor 26, radio- frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio- frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge- coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio- frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers 50 and/or one or more low-noise amplifier circuits 52), signal attenuators, impedance matching circuitry (e.g., circuitry that helps to match the impedance of antenna 42 to the impedance of radio- frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PAs) 50 in the transmit (uplink) path. A power amplifier 50 (sometimes referred to as a radio- frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

FIG. 3 is a diagram of an illustrative transmit path 58 of wireless circuitry 24. Transmit path 58 is sometimes also referred to herein as transmit chain 58 or transmit circuitry 58. As shown in FIG. 3, wireless circuitry 24 may include processing circuitry such as one or more processors 26, a converter circuitry block such as converter circuitry 54, radio-frequency amplifier circuitry such as radio-frequency amplifier 50 (e.g., a power amplifier), and an antenna 42 configured to radiate radio-frequency signals output by amplifier 50. Additional components (not shown) may also be disposed at different locations along transmit path 58 if desired.

Amplifier 50 may be disposed on FEM 40 or in transceiver circuitry 28 of FIG. 2. Processor(s) 26 may represent one or more processors such as a baseband processor, an application processor, a digital signal processor, a microcontroller, a microprocessor, a central processing unit (CPU), a programmable device, a combination of these circuits, and/or one or more processors within circuitry 18 of FIG. 1. Processor(s) 26 may be configured to generate a digital baseband signal Dbb (e.g., a stream of digital data bits at baseband). Signal Dbb is sometimes referred to as a digital signal or a transmit signal. As examples, the signal Dbb generated by processor(s) 26 may include in-phase (I) and quadrature-phase (Q) signals, radius and phase signals, a vector input, or other digitally coded signals.

In implementations that are described herein as an example, amplifier 50 is implemented as a polar power amplifier (PA). Amplifier 50 is therefore sometimes also referred to herein as polar PA 50, polar radio-frequency amplifier 50, or polar amplifier 50. Polar amplifiers may, for example, be more easily scalable during fabrication/manufacture of wireless circuitry 24 than non-polar amplifier architectures. Implementing amplifier 50 as a polar amplifier may also allow transmit circuitry 58 to be implemented without additional/dedicated mixers for upconverting signals to radio frequencies (e.g., because amplifier 50 is driven using local oscillator signals in a manner that causes the amplifier to output an amplified signal at radio frequencies, as radio-frequency signal RFSIG).

When implemented as a polar amplifier, amplifier 50 may include a first power supply voltage terminal or input such as power supply input 68 (sometimes also referred to herein as power supply terminal 68 or power supply input terminal 68). Amplifier 50 may also include a second power supply voltage terminal or input such as a reference voltage input coupled to reference voltage 66 (e.g., a ground voltage, VSS, or another reference potential). The reference voltage input and power supply input 68 may, for example, form power supply voltage rails for amplifier 50.

Amplifier 50 may also include a clocking terminal or input that is different from power supply input 68 such as local oscillator (LO) input 70 (sometimes also referred to herein as LO terminal(s) 70 or LO input terminal(s) 70). Amplifier 50 may receive an LO signal at its LO input 70. In implementations that are described herein as an example, the LO signal may include a differential LO signal pair that includes a first (positive) LO signal LOP and a second (negative) LO signal LON. Amplifier 50 may receive a power supply voltage such as power supply voltage VDD at its power supply input 68. Amplifier 50 may generate radio-frequency signal RFSIG using local oscillator signals LOP and LON and using power supply voltage VDD (e.g., without use of upconversion or mixer circuitry that is separate from amplifier 50).

The input of converter circuitry 54 may be communicatively coupled to the output of processor 26. Converter circuitry 54 may have a first output communicatively coupled to the LO input 70 of amplifier 50 over signal path 60. Converter circuitry 54 may also have a second output communicatively coupled to the power supply input 68 of amplifier 50 over signal path 62. Signal path 60 is sometimes also referred to herein as phase signal path 60. Signal path 62 is sometimes also referred to herein as amplitude signal path 62.

Converter circuitry 54 may include signal conversion circuitry such as digital-to-analog converter (DAC) circuitry and cartesian-to-polar converter circuitry. The cartesian-to-polar converter circuitry may be implemented using one or more digital signal processors in converter circuitry 54, as an example. The cartesian-to-polar converter circuitry may convert signal Dbb from a single signal in cartesian coordinates into two different signals in polar coordinates. The two signals in polar coordinates may include an amplitude signal (waveform) A(t) and a corresponding phase signal (waveform) 0(t).

Amplitude signal A(t) represents the amplitude of signal Dbb at times t and phase signal 0(t) represents the phase of signal Dbb at the same times t. The DAC circuitry in converter circuitry 54 may include, for example, a first DAC (e.g., a first set of one or more DAC cells) that converts amplitude signal A(t) from the digital domain to the analog domain and may include a second DAC (e.g., a second set of one or more DAC cells) that converts phase signal 0(t) from the digital domain to the analog domain. Converter circuitry 54 may output amplitude signal A(t) onto signal path 62 (in the analog domain). Converter circuitry 54 may concurrently output phase signal 0(t) onto signal path 60 (in the analog domain).

If desired, wireless circuitry 24 may include amplifier circuitry such as envelope amplifier 64 disposed on signal path 62 between converter circuitry 54 and amplifier 50. Envelope amplifier 64 may amplify (scale) amplitude signal A(t) to produce the power supply voltage VDD provided to amplifier 50 (e.g., power supply voltage VDD may vary over time according to amplitude signal A(t) or, equivalently, amplitude signal A(t) may represent power supply voltage VDD prior to scaling by envelope amplifier 64). If desired, envelope amplifier 64 may be replaced with any desired power supply voltage generation circuitry (e.g., a power supply integrated circuit, a power management unit, an envelope tracking integrated circuit, etc.) that generates power supply voltage VDD based on amplitude signal A(t) (e.g., by scaling or otherwise processing amplitude signal A(t)). Alternatively, envelope amplifier 64 may be omitted and power supply voltage VDD may be formed from amplitude signal A(t) without scaling or amplification. In general, power supply voltage VDD may be a voltage waveform that encodes or carries the amplitude information (modulation) for/of the radio-frequency signal RFSIG to be output by amplifier 50 (e.g., as represented by amplitude signal A(t)). Power supply input 68 is sometimes also referred to herein as the amplitude modulated or amplitude modulation (AM) input of amplifier 50.

Wireless circuitry 24 may include clocking circuitry such as an LO generator 56 disposed on signal path 60 between converter circuitry 54 and amplifier 50. LO generator 56 may generate the local oscillator signals LOP and LON provided to LO input 70 of amplifier 50 based on phase signal 0(t) (e.g., local oscillator signals LOP and LON may encode phase information (modulations) for the radio-frequency signal RFSIG to be output by amplifier 50). LO generator 56 may include, for example, a synthesizer, signal generator, oscillator circuitry (e.g., a crystal oscillator, a voltage-controlled oscillator (VCO), etc.), loop circuitry (e.g., one or more phase-locked loops, frequency-locked loops, etc.), and/or any other desired circuitry that converts phase signal 0(t) into local oscillator signals LOP and LON. More generally, local oscillator signals LOP and LON may be any desired oscillating or periodic clock signals that are used to drive amplifier 50 with the phase modulation output by converter circuitry 54 (e.g., with the phase modulation of the radio-frequency signal RFSIG to be transmitted). The phase modulation (encoding) performed by amplifier 50 under control by local oscillator signals LOP and LON (e.g., based on phase signal 0(t)) and/or the amplitude modulation (encoding) performed by amplifier 50 under control by power supply voltage VDD (e.g., based on amplitude signal A(t)) may collectively represent the wireless data carried by signal Dbb (e.g., converter circuitry 54 may convert wireless data in signal Dbb, such as baseband data representing a stream of symbols, packets, frames, datagrams, etc., into a time-varying amplitude modulation carried by amplitude signal A(t) and a time-varying phase modulation carried by phase signal 0(t)).

During signal transmission, local oscillator signals LOP and LON may drive amplifier 50 while amplifier 50 is concurrently powered using the corresponding voltage waveform of power supply voltage VDD. This may cause amplifier 50 to output an amplified radio-frequency signal RFSIG in a corresponding frequency band at its output. Radio-frequency signal RFSIG may have a phase (as a function of time) that is given by local oscillator signals LOP and LON and phase signal 0(t). Radio-frequency signal RFSIG may have a corresponding magnitude or amplitude (as a function of time) that is given by power supply voltage VDD and amplitude signal A(t). Antenna 42 may radiate radio-frequency signal RFSIG.

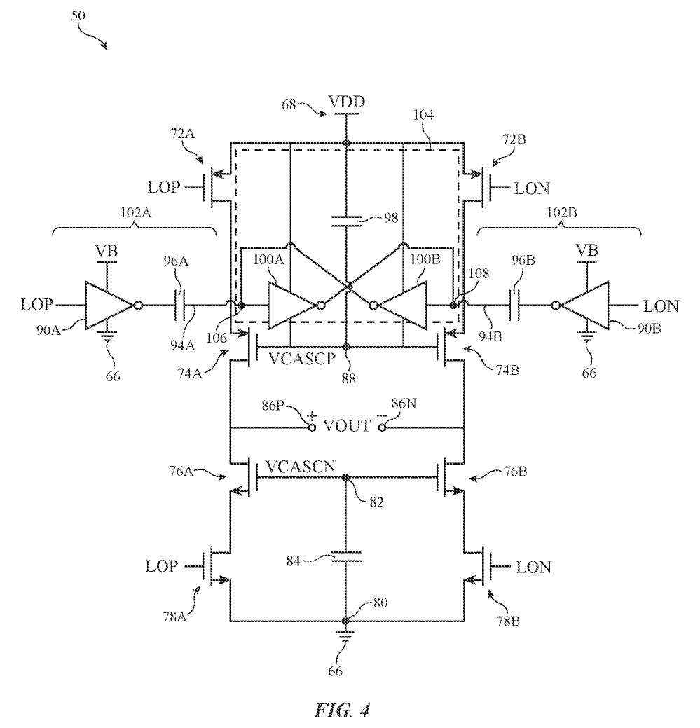

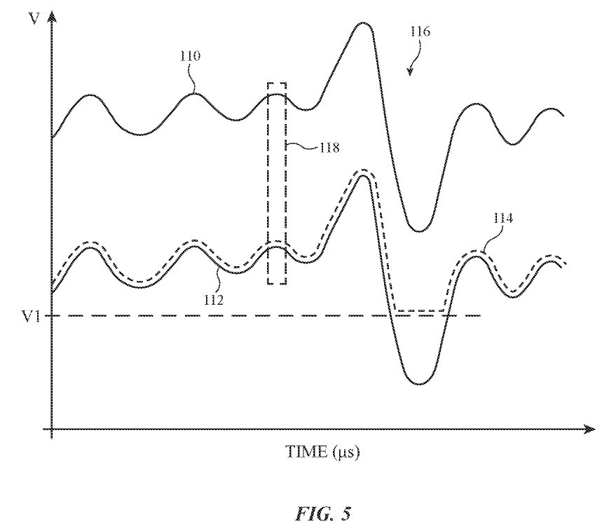

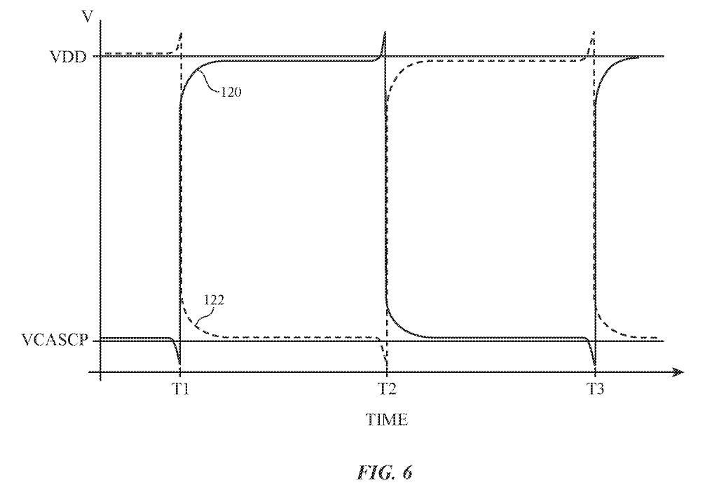

FIG. 4 is a circuit diagram of amplifier 50 (e.g., a polar amplifier that generates radio- frequency signal RFSIG based on local oscillator signals LON and LOP and power supply voltage VDD). As shown in FIG. 4, amplifier 50 may include a first common source transistor stage that includes common source transistors 72A and 72B, a first cascode transistor stage that includes transistors 74A and 74B, a second cascode transistor stage that includes transistors 76A and 76B, and a second common source transistor stage that includes common source transistors 78A and 78B, all coupled in series between power supply input 68 and reference voltage 66. Transistors 72A, 74A, 76A, and 78A may be coupled in series between power supply input 68 and reference voltage 66. Transistors 72B, 74B, 76B, and 78B may be coupled in series between power supply input 68 and reference voltage 66. Transistors 72A, 74A, 76A, and 78A may be coupled in parallel with transistors 72B, 74B, 76B, and 78B between power supply input 68 and reference voltage 66.

The first common source stage may be, for example, a common source p-channel metal- oxide-semiconductor (PMOS) stage and transistors 72A and 72B may be PMOS transistors. Transistors 72A and 72B are sometimes also referred to herein as p-type transistors 72A and 72B, p-type common source transistors 72A and 72B, PMOS transistors 72A and 72B, common source transistors 72A and 72B, or PMOS common source transistors 72A and 72B. The first cascode stage may be, for example, a PMOS cascode stage and transistors 74A and 74B may be PMOS transistors. Transistors 74A and 74B are sometimes also referred to herein as p-type transistors 74A and 74B, p-type cascode transistors 74A and 74B, PMOS transistors 74A and 74B, PMOS cascode transistors 74A and 74B, or simply as cascode transistors 74A and 74B.

The second cascode stage may be, for example, an n-channel metal-oxide- semiconductor (NMOS) stage and transistors 76A and 76B may be NMOS transistors. Transistors 76A and 76B are sometimes also referred to herein as n-type transistors 76A and 76B, n-type cascode transistors 76A and 76B, NMOS transistors 76A and 76B, NMOS cascode transistors 76A and 76B, or simply as cascode transistors 76A and 76B. The second common source stage may be, for example, a common source NMOS stage and transistors 78A and 78B may be NMOS transistors. Transistors 78A and 78B are sometimes also referred to herein as n- type transistors 78A and 78B, n-type common source transistors 78A and 78B, NMOS transistors 78A and 78B, common source transistors 78A and 78B, or NMOS common source transistors 78A and 78B. In this way, amplifier 50 may be implemented as a complementary metal-oxide-semiconductor (CMOS) cascode amplifier, where the first common source stage and the first cascode stage form a PMOS portion or block of the amplifier and where the second common source stage and the second cascode stage form an NMOS portion or block of the amplifier.

The terms "source" and "drain" are sometimes used interchangeably when referring to current-conducting terminals of a metal-oxide-semiconductor (MOS) transistor. The source and drain terminals are therefore sometimes referred to as "source-drain" terminals (e.g., a transistor has a gate terminal, a first source-drain terminal, and a second source-drain terminal). Transistors 72A and 72B may each have a respective first source-drain terminal (e.g., source terminals) coupled to power supply input 68 for receiving power supply voltage VDD. Transistors 72A and 72B may each have a respective second source-drain terminal (e.g., drain terminals) coupled to the first cascode stage. For example, the second source-drain terminal of transistor 72A may be coupled to a first source-drain terminal (e.g., source terminal) of cascode transistor 74A. The second source-drain terminal of transistor 72B may be coupled to a first source-drain terminal (e.g., source terminal) of cascode transistor 74B.

Similarly, transistors 78A and 78B may each have a respective first source-drain terminal (e.g., source terminals) coupled to reference voltage 66. Transistors 78A and 78B may each have a respective second source-drain terminal (e.g., drain terminals) coupled to the second cascode stage. For example, the second source-drain terminal of transistor 78A may be coupled to a first source-drain terminal (e.g., source terminal) of cascode transistor 76A. Similarly, the second source-drain terminal of transistor 78B may be coupled to a first source-drain terminal (e.g., source terminal) of cascode transistor 76B. The second source-drain terminal (e.g., drain terminal) of cascode transistor 76A may be coupled to the second source-drain terminal (e.g., drain terminal) of cascode transistor 74A. The second source-drain terminal (e.g., drain terminal) of cascode transistor 76B may be coupled to the second source-drain terminal (e.g., drain terminal) of cascode transistor 74B.

Amplifier 50 may have a radio-frequency output 86 coupled between the first and second cascode stages (e.g., between the PMOS and NMOS portions of amplifier 50). Radio- frequency output 86 may include a first (positive) radio-frequency output terminal 86P coupled to the second source-drain terminals (e.g., drain terminals) of transistors 74A and 76A. Radio- frequency output 86 may also include a second (negative) radio-frequency output terminal 86N coupled to the second source-drain terminals (e.g., drain terminals) of transistors 74B and 76B. During signal transmission, amplifier 50 may produce an output voltage VOUT across its output terminals 86P and 86N. Output voltage VOUT may, for example, be a voltage waveform of the radio-frequency signal RFSIG (FIG. 3) output by amplifier 50 to antenna 42.

The gate terminals of common source transistors 72A, 72B, 78A, and 78B may be coupled to signal path 60 (FIG. 3) for receiving local oscillator signals LO (e.g., the gate terminals may form part of the LO input 70 of amplifier 50, which is sometimes also referred to herein as the phase modulated or phase modulation (PM) input of amplifier 50). The gate terminals of common source transistors 72A and 78A may, for example, each receive local oscillator signal LOP from signal path 60 (e.g., may be operably coupled to a first (positive) LO input terminal of signal path 60). At the same time, the gate terminals of common source transistors 72B and 78B may receive local oscillator signal LON from signal path 60 (e.g., may be operably coupled to a second (negative) LO input terminal of signal path 60). Local oscillator signal LOP may drive the gate terminals of transistors 72A and 78A to selectively activate or deactivate transistors 72A and 78A (e.g., to cause or stop current flow between the source-drain terminals of transistors 72A and 78A). Local oscillator signal LON may drive the gate terminals of transistors 72B and 78B to selectively activate or deactivate transistors 72A and 78B (e.g., to selectively cause or stop current flow between the source-drain terminals of transistors 72B and 78B).

The term "activate" with respect to a switch (or transistor) may refer to or be defined herein as an action that places the switch in an "on" or low-impedance state such that the two terminals of the switch are electrically connected to conduct current. Activating a switch can sometimes be referred to as turning on or closing a switch. The term "deactivate" with respect to a switch (or transistor) may refer to or be defined herein as an action that places the switch in an "off' or high-impedance state such that the two terminals of the switch/transistor are electrically disconnected with minimal leakage current. Deactivating a switch can sometimes be referred to as turning off or opening a switch.

The gate terminals of transistors 76A and 76B may both be coupled to reference voltage 66 by capacitance 84 (e.g., one or more capacitors). For example, the gate terminals of transistors 76A and 76B may each be coupled to circuit node 82 (sometimes also referred to herein as cascode node 82, NMOS cascode node 82, or cascode gate node 82). Capacitance 84 may be coupled in series between circuit node 82 and circuit node 80 (e.g., capacitance 84 may include one or more capacitors coupled together in series, in parallel, or in any other desired manner between circuit nodes 82 and 80, may include one or more distributed capacitances, etc.). The first source-drain terminals (e.g., source terminals) of transistors 78A and 78B may both be coupled to circuit node 80. Circuit node 80 may be coupled to or may otherwise receive reference voltage 66. Circuit node 80 may, for example, form a power supply voltage input or terminal (e.g., a reference, ground, or VSS input or terminal) of amplifier 50.

The gate terminals of transistors 74A and 74B may both be coupled to circuit node 88 (sometimes also referred to herein as cascode node 88, PMOS cascode node 88, or cascode gate node 88). Cascode node 88 may be coupled to power supply input 68 by, via, through, or over capacitance 98 (e.g., one or more capacitors). Capacitance 98 may be coupled in series between cascode node 88 and power supply input 68 (e.g., capacitance 98 may include one or more capacitors coupled together in series, in parallel, or in any other desired manner between cascode node 88 and power supply input 68, may include one or more distributed capacitances, etc.). In this way, power supply input 68 and the first source-drain terminals (e.g., source terminals) of transistors 72A and 72B may be coupled to a first side, end, electrode, terminal, or plate of capacitance 98. Cascode node 88 may be coupled to a second side, end, electrode, terminal, or plate of capacitance 98. Capacitance 98 is sometimes also referred to herein as cascode capacitance 98 (e.g., containing one or more cascode capacitors).

In some implementations, during signal transmission, a supply-referred bias generator is used to generate a first bias voltage based on power supply voltage VDD and supplies the first bias voltage to cascode node 88. At the same time, a ground-referred bias generator is used to generate a second bias voltage based on power supply voltage VDD and supplies the second bias voltage to circuit node 82. Power supply voltage VDD drives power supply input 68 of amplifier 50 with the amplitude-modulated component of the radio-frequency signal RFSIG output by amplifier 50 at output 86. The bias voltage produced by the supply-referred bias generator and power supply voltage VDD may cause a cascode voltage VCASCP to be produced at cascode node 88. At the same time, the bias voltage produced by the ground-referred bias generator and reference voltage 66 may cause a cascode voltage VCASCN to be produced at circuit node 82.

Local oscillator signals LON and LOP drive the gate terminals of transistors 72A, 72B, 78A, and 78B (e.g., according to the phase-modulation given by the phase signal output by converter circuitry 54 of FIG. 3), cascode voltage VCASCP drives the gate terminals of transistors 74A and 74B, and cascode voltage VCASCN drives the gate terminals of transistors 76A and 76B, causing varying amounts of current to flow between the source-drain terminals of each of the cascode transistors to produce a corresponding voltage VOUT at output 86 (e.g., radio-frequency signal RFSIG of FIG. 3). Voltage VOUT may exhibit a phase modulation over time as given by local oscillator signals LOP and LON (e.g., based on phase signal 0(t) of FIG. 3) and may exhibit an amplitude modulation over time as given by power supply voltage VDD. The phase and/or amplitude modulations may carry or encode the wireless data of signal Dbb (FIG. 3).

In this way, the supply-referred bias generator may cause cascode voltage VCASCP to track the AM waveform of the power supply voltage VDD received at power supply input 68. However, the supply-referred bias generator is unable to provide a bias voltage at magnitudes exceeding the present magnitude of power supply voltage VDD and reference voltage 66. Because polar modulation may require power supply voltage VDD to drop to relatively low magnitudes during signal transmission (e.g., to voltages of 0.5 V or less), this may cause cascode voltage VCASCP to become clipped at relatively low magnitudes near 0 V, which may push the PMOS transistors into a sub-threshold region and may produce a drastic drop of phase shift in the signal output by the amplifier. This is clipping of cascode voltage VCASCP is shown by curve 114 in FIG. 5.

Curve 110 of FIG. 5 plots power supply voltage VDD as a function of time (e.g., carrying an amplitude modulation as given by amplitude signal A(t) of FIG. 1). As shown by curve 114, when power supply voltage VDD drops to a magnitude below a threshold voltage V1 (e.g., 0.5 V), such as when the amplitude modulation includes a relatively large minimum 116, cascode voltage VCASCP becomes clipped, clamped, or limited to threshold voltage V1. This causes cascode voltage VCASCP and thus voltage VOUT to incorrectly or incompletely track the full amplitude modulation of power supply voltage VDD (e.g., effectively losing information encoded by the amplitude modulation associated with minimum 116 in power supply voltage VDD).

To mitigate these issues, the PMOS cascode stage of amplifier 50 may be biased using a dynamic bias voltage that is generated based on local oscillator signals LOP and LON and an additional voltage such as bias voltage VB. Returning to FIG. 4, for example, amplifier 50 may include dynamic level shifting circuitry and a cross-coupled inverter stage for dynamically biasing the PMOS cascode stage of amplifier 50 based on local oscillator signals LOP and LON. As shown in FIG. 4, the dynamic level shifting circuitry may include a first (positive) dynamic level shifter 102A and a second (negative) dynamic level shifter 102B. The cross-coupled inverter stage may include a first inverter 100A that is cross-coupled with a second inverter 100B. Inverters 100A and 100B may be coupled between the outputs of dynamic level shifters 102A and 102B.

Dynamic level shifter 102A (sometimes also referred to herein as a dynamic level shifting circuit, dynamic level shifting circuitry, or a dynamic PMOS cascode bias circuit) may include amplifier circuitry such as inverter 90A. The input of inverter 90A may receive local oscillator signal LOP (e.g., may be coupled to a positive terminal of signal path 60 of FIG. 3). The output of inverter 90A may be coupled to the input of inverter 100A over a positive biasing line such as bias line 94A. A level shifting capacitance such as capacitance 96A may be disposed on bias line 94A and may be coupled in series between the output of inverter 90A and the input of inverter 100A. Capacitance 96A may include one or more capacitors coupled in series and/or parallel between inverters 90A and 100A, one or more distributed capacitances, etc. Inverter 90A may have a first (e.g., PMOS) power supply input or terminal that receives bias voltage VB and may have a second (e.g., NMOS) power supply input or terminal that receives reference voltage 66 (e.g., the biasing or power supply inputs of inverter 90A may be coupled between power supply voltage rails formed from bias voltage VB and reference voltage 66). If desired, a supply-referred bias generator (not shown) may generate bias voltage VB based on power supply voltage VDD and may power inverter 90A using bias voltage VB.

Similarly, dynamic level shifter 102B may include amplifier circuitry such as inverter 90B. The input of inverter 90B may receive local oscillator signal LON (e.g., may be coupled to a negative terminal of signal path 60 of FIG. 3). In this way, the gate terminals of transistors 72A, 72B, 78A, and 78B and the inputs of dynamic level shifters 102A and 102B (e.g., the inputs of inverters 90A and 90B) may collectively form the LO input 70 (FIG. 3) of amplifier 50. The output of inverter 90B may be coupled to the input of inverter 100B over a negative biasing line such as bias line 94B. A level shifting capacitance such as capacitance 96B may be disposed on bias line 94A and may be coupled in series between the output of inverter 90B and the input of inverter 100B. Capacitance 96B may include one or more capacitors coupled in series and/or parallel between inverters 90B and 100B, one or more distributed capacitances, etc. Inverter 90B may have a first (e.g., PMOS) power supply input that receives bias voltage VB and may have a second (e.g., NMOS) power supply input (e.g., a reference or ground terminal) that receives reference voltage 66 (e.g., the biasing or power supply inputs of inverter 90B may be coupled between power supply voltage rails formed from bias voltage VB and reference voltage 66).

The output of inverter 100A may be communicatively coupled to the input of inverter 100B and the output of inverter 90B. For example, as shown in FIG. 4, the output of inverter 100A may be coupled to a negative dynamic bias terminal or node such as circuit node 108 on bias line 94B. Circuit node 108 may be interposed on bias line 94B between inverter 100B and capacitance 96B. Similarly, the output of inverter 100B may be communicatively coupled to the input of inverter 100A and the output of inverter 90A. For example, as shown in FIG. 4, the output of inverter 100B may be coupled to a positive dynamic bias terminal or node such as circuit node 106 on bias line 94A. Circuit node 106 may be interposed on bias line 94A between inverter 100A and capacitance 96A.

Within the cross-coupled inverter stage, inverter 100A may have a first (e.g., PMOS) power supply input (terminal) that is coupled to power supply input 68 and the first source-drain terminals of transistors 72A and 72B. Inverter 100B may also have a second (e.g., NMOS) power supply input (e.g., a reference or ground terminal) that is coupled to cascode node 88. Similarly, inverter 100B may have a first (e.g., PMOS) power supply input (terminal) that is coupled to power supply input 68 and the first source-drain terminals of transistors 72A and 72B. Inverter 100B may also have a second (e.g., NMOS) power supply input (e.g., a reference or ground terminal) that is coupled to cascode node 88. In this way, the biasing or power supply inputs of inverter 100A may be coupled between power supply voltage rails formed from power supply voltage VDD and cascode voltage VCASCP. Similarly, the biasing or power supply inputs of inverter 100A may be coupled between power supply voltage rails at power supply voltage VDD and cascode voltage VCASCP. The inverters 100A and 100B and the capacitance 98 within the PMOS cascode portion of amplifier 50 are sometimes referred to collectively herein as dynamic charge pump circuitry 104 or dynamic charge pump 104. Circuit nodes 106 and 108 are sometimes also referred to herein as intermediate nodes or intermediate circuit nodes of dynamic charge pump 104.

During signal transmission, inverter 90A may amplify (e.g., invert) local oscillator signal LOP based on bias voltage VB and reference voltage 66 to drive/charge capacitance 96A. Capacitance 96A may serve to shift the DC level of the output of inverter 90A (e.g., local oscillator signal LOP), which drives or produces a level-shifted voltage onto circuit node 106. Inverter 100A may drive an inverted version of the voltage at circuit node 106 onto circuit node 108. At the same time, inverter 90B may amplify (e.g., invert) local oscillator signal LON based on bias voltage VB and reference voltage 66 to drive/charge capacitance 96B. Capacitance 96B may serve to shift the DC level of the output of inverter 90B (e.g., local oscillator signal LON), which drives or produces a level-shifted voltage onto circuit node 108. Inverter 100A may drive an inverted version of the voltage at circuit node 108 onto circuit node 106. In this way, the dynamic level shifters may shift the local oscillator signals to the DC level of power supply voltage VDD at circuit nodes 106 and 108. The swing in amplitude of the voltages between circuit nodes 106 and 108 may be set, via dynamic level shifters 102A and 102B, by bias voltage VB (e.g., may be equal to bias voltage VB).

The voltage swing between circuit nodes 106 and 108 may drive dynamic charge pump 104, which charges the capacitance 98 coupled to cascode node 88. The difference in voltage between the cascode voltage VCASCP on cascode node 88 and power supply voltage VDD is the same as the voltage swing amplitude of circuit nodes 106 and 108, which is equal to bias voltage VB. Put differently, dynamic charge pump 104 and dynamic level shifters 102A/102B may shift the voltage swing between circuit nodes 106 and 108, which is equal to bias voltage VB, to a voltage equal to VDD - VB at cascode node 88. This voltage at cascode node 88 forms cascode voltage VCASC (e.g., VB = VDD - VCASC or equivalently VCASC = VDD - VB). Bias voltage VB does not itself need to track the amplitude modulation of power supply voltage VDD, so its bandwidth requirement may be relatively relaxed. When driven using dynamic charge pump 104 and dynamic level shifters 102A and 102B, cascode voltage VCASCP may very rapidly track all of the amplitude modulation in power supply voltage VDD without clipping, even as power supply voltage VDD drops to levels below threshold V1 (FIG. 5).

Curve 144 of FIG. 5 illustrates the cascode voltage VCASCP at cascode node 88 when driven using dynamic level shifters 102A and 102B and dynamic charge pump 104. As shown by curve 112, cascode voltage VCASCP drops below threshold voltage V1 when power supply voltage VDD exhibits minimum 116 and is not clipped, clamped, or limited to threshold voltage V1. The difference between curve 110 and curve 112 at each time t may correspond to the voltage swing between circuit nodes 102 and 104 at times t, which may be equal to the bias voltage VB used to power the inverters 90A and 90B in dynamic level shifters 102A and 102B. In this way, cascode voltage VCASCP and thus voltage VOUT may correctly, completely, and rapidly track the full amplitude modulation of power supply voltage VDD (e.g., effectively preserving all information encoded by the amplitude modulation associated with minimum 116 in power supply voltage VDD in the radio-frequency signal RFSIG output by amplifier 50).

FIG. 6 illustrates voltage waveforms (e.g., voltage (V) over time t) at different nodes of amplifier 50 during signal transmission (e.g., as viewed within exploded region 118 of FIG. 5). Curve 120 plots the voltage at circuit node 108. Dashed curve 122 plots the voltage at circuit node 106. Dynamic charge pump 104 may cause the voltage at circuit node 108 to begin to rise when the voltage at circuit node 106 falls (e.g., at times T1 and T2). Conversely, dynamic charge pump 104 may cause the voltage at circuit node 106 may begin to rise when the voltage at circuit node 108 falls (e.g., at time T2). As shown by curves 122 and 120, the voltages at circuit nodes 106 and 108 may swing between power supply voltage VDD (e.g., corresponding to curve 110 of FIG. 5) and cascode voltage VCASCP (e.g., corresponding to curve 112 of FIG. 5) as local oscillator signals LOP and LON continue to drive the LO input 70 (FIG. 3) of amplifier 50. The difference between curves 120 and 122 at any given time (e.g., the voltage swing between circuit nodes 106 and 108) may be equal to the bias voltage VB used to power dynamic level shifters 102A and 102B.

The absence of clipping in cascode voltage VCASCP even as power supply voltage VDD drops to relatively low levels may also help to improve amplitude modulation to amplitude modulation (AMAM) distortion and amplitude modulation to phase modulation (AMPM) distortion of amplifier 50 relative to implementations where dynamic level shifters 102A/102B and dynamic charge pump 104 are omitted. FIG. 7 includes plots showing how dynamic level shifters 102A/102B and dynamic charge pump 104 may improve AMAM distortion and AMPM distortion for amplifier 50 across different levels of power supply voltage VDD.

Curve 124 of FIG. 7 plots, as a function of power supply voltage VDD, the AMAM distortion of amplifier 50 while dynamically biased at its PMOS cascode stage by dynamic level shifters 102A/102B and dynamic charge pump 104. Curve 126 plots the AMAM distortion of amplifier 50 in the absence of dynamic level shifters 102A/102B and dynamic charge pump 104. Curve 130 plots the AMPM distortion of amplifier 50 while dynamically biased at its PMOS cascode stage by dynamic level shifters 102A/102B and dynamic charge pump 104. Curve 128 plots the AMPM distortion of amplifier 50 in the absence of dynamic level shifters 102A/102B and dynamic charge pump 104. As shown by curves 124-130, the presence of clipping in cascode voltage VCASC at power supply voltages VDD less than threshold V1 (e.g., 0.5 V) may produce substantial non-linear AMAM distortion and non-linear AMPM distortion at amplifier 50, which may reduce the overall wireless performance of transmit circuitry 58 (FIG. 3). Conversely, dynamic level shifters 102A/102B and dynamic charge pump 104 may effectively decrease, mitigate, or eliminate non-linearity in the AMAM distortion and AMPM distortion of amplifier 50 by allowing cascode voltage VCASC to drop below threshold voltage V1 when power supply voltage VDD falls below threshold voltage V1.

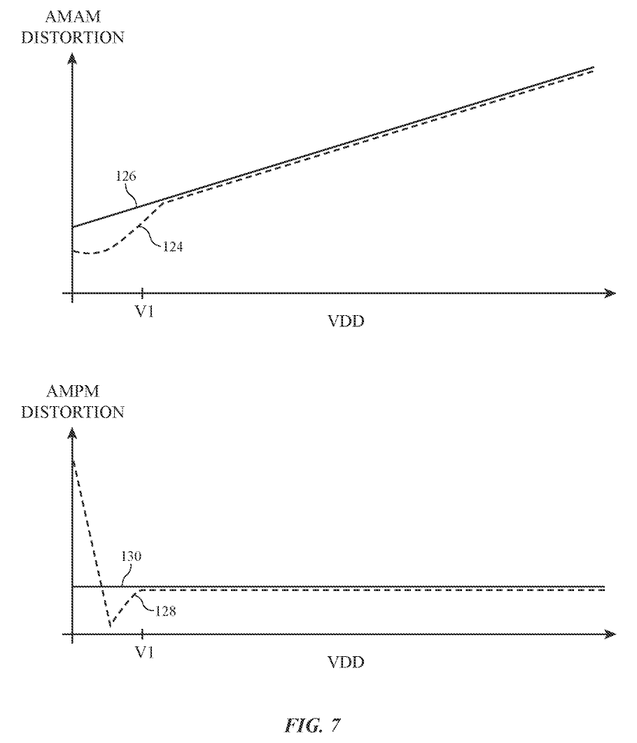

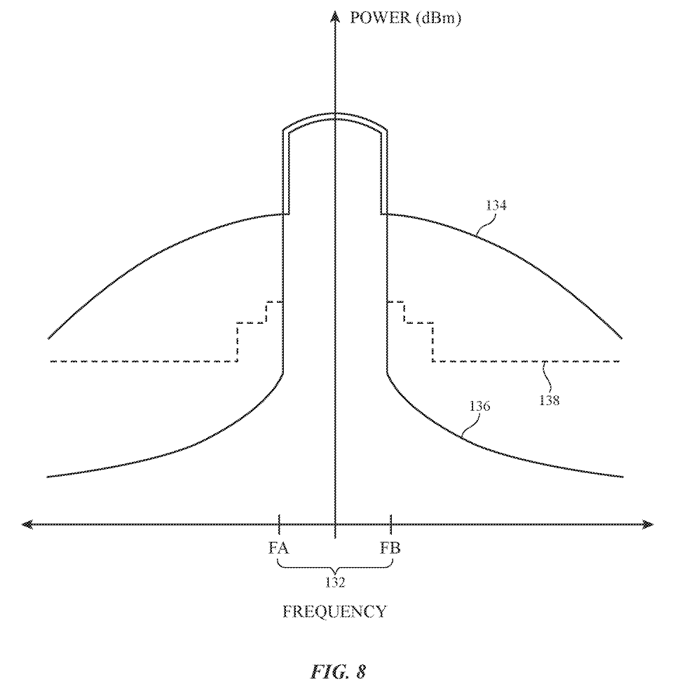

The absence of clipping in cascode voltage VCASCP even as power supply voltage VDD drops to relatively low levels may also help to improve the adjacent channel leakage ratio (ACLR) of amplifier 50 relative to implementations where dynamic level shifters 102A/102B and dynamic charge pump 104 are omitted. FIG. 8 is a plot showing how dynamic level shifters 102A/102B and dynamic charge pump 104 may improve ACLR for amplifier 50.

Curve 134 plots the signal level (e.g., power) of radio-frequency signal RFSIG (output voltage VOUT) as a function of frequency F in the absence of dynamic level shifters 102A/102B and dynamic charge pump 104 in amplifier 50. Transmit circuitry 58 may transmit radio- frequency signal RFSIG within a corresponding frequency allocation 132 extending from frequency FA to frequency FB. Frequency allocation 132 may span one or more continuous resource blocks, resource elements, sub-channels, and/or another set of frequency spectrum/resources, and is sometimes also referred to herein as frequency range 132 (e.g., a continuous set of resource blocks/elements, a frequency channel, some or all of frequency/communications band, etc.). Frequency allocation 132 may be determined by a communication schedule for device 10 (e.g., as maintained by a wireless network), by one or more applications running on device 10, by one or more communications requirements imposed on device 10, etc.

As shown by curve 134, radio-frequency signals RFSIG may exhibit a signal peak within frequency allocation 132. However, the presence of clipping in the cascode voltage VCASCP at cascode node 88 (see, e.g., curve 114 of FIG. 5) may cause radio-frequency signal RFSIG to exhibit a relatively high signal level at frequencies outside of frequency allocation 132 (e.g., where the signal level gradually drops as an offset from frequency allocation 132 increases). This may cause amplifier 50 to exhibit a relatively high or excessive ACLR. The signal level of radio-frequency signal RFSIG may, for example, exceed a threshold or limit such as emissions mask 138. Emissions mask 138 may represent an upper limit (e.g., as imposed on device 10 by the manufacturer of device 10 or wireless circuitry 24, a regulatory agency or body, a communications protocol or standard governing transmissions by transmit circuitry 58, one or more applications running on device 10, etc.). Exceeding emissions mask 138 outside of frequency allocation 132 may, for example, cause wireless circuitry 24 to fail the emissions mask and/or may otherwise deteriorate the wireless performance of the amplifier, other circuitry in device 10, and/or an external device that receives the radio-frequency signal.

Curve 136 plots the signal level of radio-frequency signal RFSIG as a function of frequency when amplifier 50 includes dynamic level shifters 102A/102B and dynamic charge pump 104. As shown by curve 136, radio-frequency signals RFSIG may still exhibit a signal peak within frequency allocation 132. However, the removal of clipping in the cascode voltage VCASCP at cascode node 88 by dynamic charge pump 104 and dynamic level shifters 102A/102B may cause radio-frequency signal RFSIG to exhibit a relatively low signal level at frequencies outside of frequency allocation 132 (e.g., where the signal level rapidly drops as an offset from frequency allocation 132 increases). This may cause amplifier 50 to exhibit a relatively low ACLR. The signal level of radio-frequency signal RFSIG may, for example, be less than emissions mask 138 at all frequencies outside of frequency allocation 132. Curves 120- 136 of FIGS. 6-8 may have other shapes in practice. As another example, dynamic level shifters 102A/102B and dynamic charge pump 104 may also serve to improve the error vector magnitude (EVM) of radio-frequency signal RFSIG by as high as 11-12 dB relative to implementations of amplifier 50 without dynamic level shifters 102A/102B and dynamic charge pump 104.

The methods and operations described above in connection with FIGS. 1-8 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random- access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

As used herein, the term "concurrent" means at least partially overlapping in time. In other words, first and second events are referred to herein as being "concurrent" with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non- simultaneous (e.g., if the first event starts before or after the start of the second event, if the first event ends before or after the end of the second event, or if the first and second events are partially non-overlapping in time). As used herein, the term "while" is synonymous with "concurrent."

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Amplifier circuitry configured to output a radio-frequency signal, the amplifier circuitry comprising:
a first common source stage configured to receive a power supply voltage that conveys an amplitude modulation for the radio-frequency signal;
a first cascode stage that includes a first transistor and a second transistor having gate terminals coupled to a cascode node;
a second cascode stage, wherein the first cascode stage is coupled between the second cascode stage and the first common source stage;
a second common source stage coupled to a reference voltage, wherein the second cascode stage is coupled between the second common source stage and the first cascode stage; and
cross-coupled inverters having power supply inputs coupled between the power supply voltage and the cascode node.

2. The amplifier circuitry of claim 1, further comprising:
a capacitance coupled in series between the power supply voltage and the cascode node.

3. The amplifier circuitry of claim 2, further comprising:
a radio-frequency output configured to transmit the radio-frequency signal, wherein the radio-frequency output is coupled between the first cascode stage and the second cascode stage.

4. The amplifier circuitry of claim 1, wherein the first common source stage comprises a third transistor and a fourth transistor, the third transistor is coupled in series between the power supply voltage and the first transistor, the fourth transistor is coupled in series between the power supply voltage and the second transistor, a gate terminal of the third transistor is configured to receive a positive local oscillator signal, a gate terminal of the fourth transistor is configured to receive a negative local oscillator signal, and the positive and negative local oscillator signals convey a phase modulation for the radio-frequency signal.

5. The amplifier circuitry of claim 4, wherein the second cascode stage comprises a fifth transistor and a sixth transistor, the first transistor is coupled in series between the fifth transistor and the third transistor, the second transistor is coupled in series between the sixth transistor and the fourth transistor, gate terminals of the fifth and sixth transistors are coupled to a circuit node, and a capacitance is coupled between the circuit node and the reference voltage.

6. The amplifier circuitry of claim 5, wherein the second cascode stage comprises a seventh transistor and an eighth transistor, the seventh transistor is coupled in series between the fifth transistor and the reference voltage, the eighth transistor is coupled in series between the sixth transistor and the reference voltage, a gate terminal of the seventh transistor is configured to receive the positive local oscillator signal, and a gate terminal of the eighth transistor is configured to receive the negative local oscillator signal.

7. The amplifier circuitry of claim 6, wherein the first, second, third, and fourth transistors are p-type transistors and the fifth, sixth, seventh, and eighth transistors are n-type transistors.

8. The amplifier circuitry of claim 4, wherein the cross-coupled converters comprise:
a first inverter having first power supply inputs coupled between the power supply voltage and the cascode node; and
a second inverter having second power supply inputs coupled between the power supply voltage and the cascode node, wherein an output of the first inverter is communicatively coupled to an input of the second inverter and wherein an output of the second inverter is communicatively coupled to an input of the first inverter.

9. The amplifier circuitry of claim 8, further comprising:
a first level shifting circuit communicatively coupled to the input of the first inverter over a first bias path, the output of the second inverter being coupled to a first circuit node on the first bias path; and
a second level shifting circuit communicatively coupled to the input of the second inverter over a second bias path, the output of the first inverter being coupled to a second circuit node on the second bias path.

10. The amplifier circuitry of claim 9, wherein the first level shifting circuit comprises:
a third inverter having an output coupled to the first bias path; and
a first capacitance disposed on the first bias path between the third inverter and the first circuit node, wherein the third inverter is configured to drive a first voltage on the first circuit node through the first capacitor based on the positive local oscillator signal and a bias voltage that is different than the power supply voltage.

11. The amplifier circuitry of claim 10, wherein the second level shifting circuit comprises:
a fourth inverter having an output coupled to the second bias path;
a second capacitance disposed on the second bias path between the fourth inverter and the second circuit node, wherein the fourth inverter is configured to drive a second voltage on the second circuit node through the second capacitor based on the negative local oscillator signal and the bias voltage; and
a third capacitance coupled between the power supply voltage and the cascode node.

12. Amplifier circuitry configured to output a radio-frequency signal, the amplifier circuitry comprising:
a first common source stage that includes a first transistor and a second transistor, wherein a gate terminal of the first transistor receives a positive local oscillator signal and a gate terminal of the second transistor receives a negative local oscillator signal;
a cascode stage, wherein the cascode stage comprises a third transistor and a fourth transistor, the first transistor is coupled in series between the third transistor and a power supply input of the amplifier circuitry, the second transistor is coupled in series between the fourth transistor and the power supply input, and gate terminals of the third and fourth transistors are coupled to a cascode node;
a first circuit configured to generate at least part of a voltage at the cascode node based on the positive local oscillator signal; and
a second circuit configured to generate at least part of the voltage at the cascode node based on the negative local oscillator signal.

13. The amplifier circuitry of claim 12, further comprising:
a charge pump coupled between the power supply input and the cascode node, wherein the charge pump is configured to generate at least part of the voltage at the cascode node.

14. The amplifier circuitry of claim 13, wherein the charge pump comprises:
a first inverter having a first power supply terminal coupled to the power supply input, a second power supply terminal coupled to the cascode node, an input communicatively coupled to the first circuit, and an output communicatively coupled to the second circuit; and
a capacitor coupled between the power supply input and the cascode node.

15. The amplifier circuitry of claim 14, wherein the charge pump further comprises:
a second inverter having a third power supply terminal coupled to the power supply input, a fourth power supply terminal coupled to the cascode node, an input communicatively coupled to the second circuit and the output of the first inverter, and an output communicatively coupled to the first circuit and the input of the first inverter.

16. The amplifier circuitry of claim 13, wherein the first circuit comprises:
a first inverter having a first power supply terminal that receives a bias voltage, a second power supply terminal that receives a reference voltage, and an input that receives the positive local oscillator signal; and
a first capacitor coupled in series between an output of the first inverter and the charge pump.

17. The amplifier circuitry of claim 16, wherein the second circuit comprises:
a second inverter having a third power supply terminal that receives the bias voltage, a fourth power supply terminal that receives the reference voltage, and an input that receives the negative local oscillator signal; and
a second capacitor coupled in series between an output of the second inverter and the charge pump, wherein the bias voltage is equal to a power supply voltage received at the power supply input minus the voltage at the cascode node.

18. The amplifier circuitry of claim 12, further comprising:
an additional cascode stage, wherein the cascode stage is coupled between the additional cascode stage and the common source stage;
an additional common source stage coupled between the additional cascode stage and a reference voltage; and
output terminals configured to output the radio-frequency signal, wherein the output terminals are coupled between the cascode stage and the additional cascode stage.

19. A polar power amplifier comprising:
a first transistor having a gate terminal that receives a positive clocking signal;
a second transistor having a gate terminal that receives a negative clocking signal, the first and second transistors having source terminals coupled to a power supply input;
a third transistor having a source terminal coupled to a drain terminal of the first transistor;
a fourth transistor having a source terminal coupled to a drain terminal of the second transistor, the third and fourth transistors having gate terminals coupled to a circuit node;
a first capacitor coupled in series between the power supply input and the circuit node;
a first inverter having power supply terminals coupled between the power supply input and the circuit node;
a second inverter having power supply terminals coupled between the power supply input and the circuit node;
a third inverter having an input that receives the positive clocking signal and having an output communicatively coupled to an input of the first inverter and an output of the second inverter; and
a fourth inverter having an input that receives the negative clocking signal and having an output communicatively coupled to an input of the second inverter and an output of the first inverter.

20. The polar power amplifier of claim 19, further comprising:
a second capacitor coupled in series between the output of the third inverter and the input of the first inverter;
a third capacitor coupled in series between the output of the fourth inverter and the input of the second inverter, wherein the third and fourth inverters are powered by a bias voltage that is different than a power supply voltage received at the power supply input;
a fifth transistor having a drain terminal coupled to a drain terminal of the third transistor;
a sixth transistor having a drain terminal coupled to a drain terminal of the fourth transistor;
a seventh transistor having a drain terminal coupled to a source terminal of the fifth transistor and having a source terminal that receives a reference voltage;
an eighth transistor having a drain terminal coupled to a source terminal of the sixth transistor and having a source terminal that receives the reference voltage;
a fourth capacitor that couples gate terminals of the seventh and eighth transistors to the reference voltage; and
a radio-frequency output between the drain terminals of the third, fourth, fifth, and sixth transistors.
